(19) United States
(12) Patent Application Publication
(10) Pub. No.: US 2025/0246246 A1
(43) Pub. Date: Jul. 31, 2025

(54) Nonvolatile Storage Device And Integrated Circuit Device

(71) Applicant: SEIKO EPSON CORPORATION, Tokyo (JP)

(72) Inventors: Takeshi MIYAZAKI, Chino (JP); Masaki SHODA, Chino (JP)

(21) Appl. No.: 19/036,551

(22) Filed: Jan. 24, 2025

(30) Foreign Application Priority Data
Jan. 26, 2024 (JP) 2024-009976

(51) Int. Cl. G11C 16/26

(52) U.S. Cl. CPC G11C 16/26

(57) ABSTRACT

A nonvolatile storage device includes a memory cell array having a plurality of nonvolatile memory cells, and a readout circuit reading out data from the memory cell array. In a first mode, the readout circuit reads out complementary data by comparing a first detection current flowing through a first memory cell with a second detection current flowing through a second memory cell. In a second mode, the readout circuit reads out the complementary data by comparing a current obtained by addition or subtraction of a first reference current to or from the first detection current with the second detection current, or reads out the complementary data by comparing the first detection current with a current obtained by addition or subtraction of a second reference current to or from the second detection current.

The present application is based on, and claims priority from JP Application Serial Number 2024-009976, filed Jan. 26, 2024, the disclosure of which is hereby incorporated by reference herein in its entirety.

### BACKGROUND

### 1. Technical Field

The present disclosure relates to a nonvolatile storage device and an integrated circuit device.

### 2. Related Art

JP-A-2011-192329 discloses a nonvolatile storage device having a single mode in which a first memory cell and a second memory cell provided in a memory cell array store separate data and a dual mode in which the memory cells store complementary data as mutually complementary data. According to the nonvolatile storage device described in JP-A-2011-192329, since the single mode and the dual mode can be optionally switched for each memory cell provided in the memory cell array, the device can be versatility used for many purposes.

JP-A-2011-192329 is an example of the related art.

In the nonvolatile storage device described in JP-A-2011-192329, when complementary data is stored in the first memory cell and the second memory cell in the dual mode, the data written in each of the first memory cell and the second memory cell is read out in the single mode in verification after writing of the complementary data. Then, whether a condition that a detection current flowing through the memory cell in which the data “1” is written of the first memory cell and the second memory cell is larger than a reference current and a detection current flowing through the memory cell in which the data “0” is written is smaller than the reference current is satisfied is determined, and data is repeatedly written in each memory cell until the condition is satisfied. As a result, excessive stress may be applied to each memory cell, and deterioration may be accelerated.

### SUMMARY

A nonvolatile storage device according to an aspect of the present disclosure includes a memory cell array having a plurality of nonvolatile memory cells including a first memory cell and a second memory cell, and a readout circuit reading out data from the memory cell array via a first node and a second node, wherein, in a first mode, the readout circuit reads out complementary data stored in the first memory cell and the second memory cell by comparing a first detection current flowing through the first memory cell electrically coupled to the first node with a second detection current flowing through the second memory cell electrically coupled to the second node, and, in a second mode, the readout circuit reads out the complementary data by comparing a current obtained by addition or subtraction of a first reference current to or from the first detection current with the second detection current, or reads out the complementary data by comparing the first detection current with a current obtained by addition or subtraction of a second reference current to or from the second detection current.

An integrated circuit device according to an aspect of the present disclosure includes the nonvolatile storage device according to the above described aspect.

### BRIEF DESCRIPTION OF THE DRAWINGS

FIG. 1 is a block diagram showing a schematic configuration of a nonvolatile storage device of an embodiment.

FIG. 2 shows a detailed configuration example of a memory cell array, a switch circuit, and a readout circuit in a first embodiment.

FIG. 3 shows a state of the readout circuit when a first mode is set in the first embodiment.

FIG. 4 shows a state of the readout circuit when a second mode is set in the first embodiment.

FIG. 5 shows another state of the readout circuit when the second mode is set in the first embodiment.

FIG. 6 shows an example of data read out in the second mode when a difference between a first detection current and a second detection current is smaller in the first embodiment.

FIG. 7 shows an example of data read out in the second mode when the difference between the first detection current and the second detection current is larger in the first embodiment.

FIG. 8 shows a margin for the difference between the first detection current and the second detection current.

FIG. 9 is a flowchart showing an example of a procedure of data reading in a first mode in the first embodiment.

FIG. 10 is a flowchart showing an example of a procedure of data reading in a second mode in the first embodiment.

FIG. 11 shows an example of data read out in a first mode and a second mode when a difference between a first detection current and a second detection current is smaller in the second embodiment.

FIG. 12 shows an example of data read out in the first mode and the second mode when the difference between the first detection current and the second detection current is larger in the second embodiment.

FIG. 13 is a flowchart showing an example of a procedure of verification by data writing and data read in the second mode in the second embodiment.

FIG. 14 is a flowchart showing an example of a procedure of data reading in the first mode and the second mode in the second embodiment.

FIG. 15 shows a state of a readout circuit when a third mode is set in a third embodiment.

FIG. 16 shows another state of the readout circuit when the third mode is set in the third embodiment.

FIG. 17 is a flowchart showing an example of a procedure of reading of data stored in a first memory cell in the third mode in the third embodiment.

FIG. 18 is a flowchart showing an example of a procedure of reading of data stored in a second memory cell in the third mode in the third embodiment.

FIG. 19 shows a detailed configuration example of a memory cell array, a switch circuit, and a readout circuit in a fourth embodiment.

FIG. 20 shows a state of the readout circuit when a first mode is set in the fourth embodiment.

FIG. 21 shows a state of the readout circuit when a second mode is set in the fourth embodiment.

FIG. 22 shows another state of the readout circuit when the second mode is set in the fourth embodiment.

FIG. 23 shows an example of data read out in the second mode when a difference between a first detection current and a second detection current is smaller in the fourth embodiment.

FIG. 24 shows an example of data read out in the second mode when the difference between the first detection current and the second detection current is larger in the fourth embodiment.

FIG. 25 is a flowchart showing an example of a procedure of data reading in the second mode in the fourth embodiment.

FIG. 26 is a functional block diagram showing a configuration example of an electronic apparatus.

### DESCRIPTION OF EMBODIMENTS

As below, preferred embodiments of the present disclosure will be described in detail using the drawings. Note that the embodiments to be described below do not unduly limit the present disclosure described in What is Claimed is. In addition, not all configurations to be described below are necessarily essential component elements of the present disclosure.

### 1. Nonvolatile Storage Device

### 1-1. First Embodiment

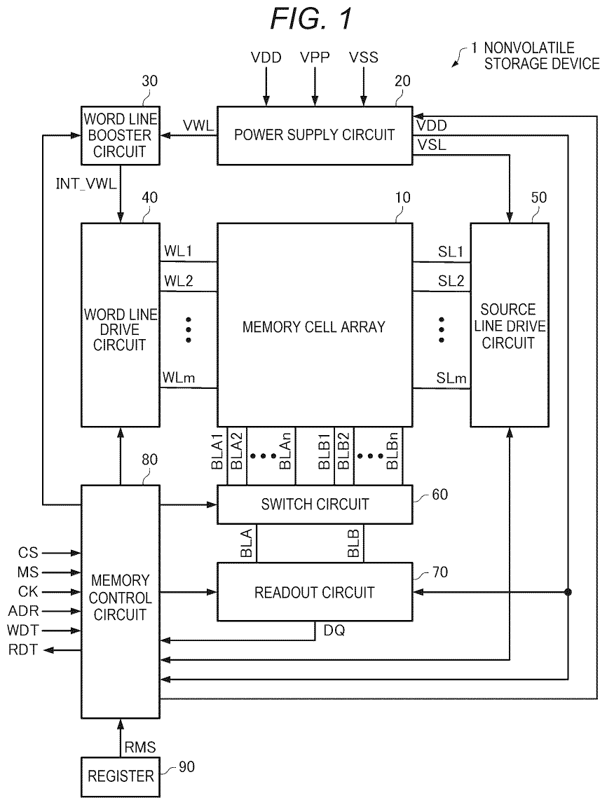

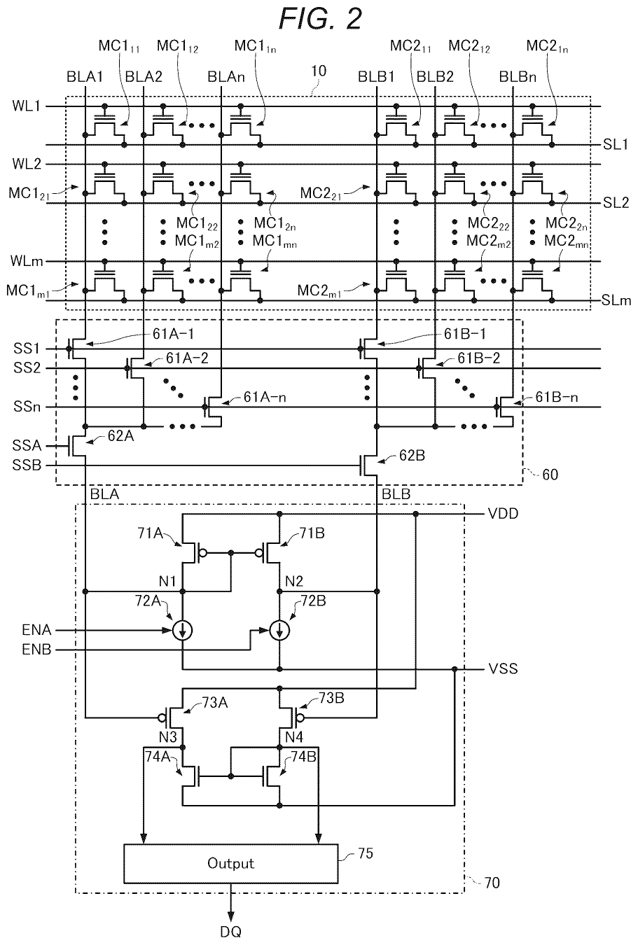

FIG. 1 is a block diagram showing a schematic configuration of a nonvolatile storage device 1 of the embodiment. As shown in FIG. 1, the nonvolatile storage device 1 includes a memory cell array 10, a power supply circuit 20, a word line booster circuit 30, a word line drive circuit 40, a source line drive circuit 50, a switch circuit 60, a readout circuit 70, a memory control circuit 80, and a register 90. FIG. 2 shows a detailed configuration example of the memory cell array 10, the switch circuit 60, and the readout circuit 70. As below, the configuration of the nonvolatile storage device 1 will be described with reference to FIGS. 1 and 2.

The memory control circuit 80 controls the power supply circuit 20, the word line booster circuit 30, the word line drive circuit 40, the source line drive circuit 50, the switch circuit 60, and the readout circuit 70 so as to cause a plurality of memory cells MC provided in the memory cell array 10 to perform an erase operation, a write operation, or a read operation.

The memory cell array 10 includes a plurality of nonvolatile memory cells MC arranged in a matrix of m rows and 2n columns. Each of m and n is an integer of 2 or more. For example, when m=2048 and n=1024, the memory cell array 10 may include 2048×2048 memory cells arranged in a matrix of 2048 rows and 2048 columns. As the memory cell MC, various types of memory cells of a MONOS-type, a floating gate-type, a ferroelectric type, a phase-change-type, a magnetoresistance-type, etc. can be assumed. MONOS is an abbreviation for Metal-Oxide-Nitride-Oxide-Silicon.

The memory cell array 10 includes m word lines WL1, WL2, . . . , WLm, m source lines SL1, SL2, . . . , SLm, n bit lines BLA1, BLA2, . . . , BLAn, and n bit lines BLB1, BLB2, . . . , BLBn. Each of the word lines WL1 to WLm is coupled to 2n memory cells MC arranged in each row. Each of the source lines SL1 to SLm is coupled to the 2n memory cells MC arranged in each row. Each of the bit lines BLA1 to BLAn is coupled to n memory cells MC of the 2n memory cells MC arranged in each column. Each of the bit lines BLB1 to BLBn is coupled to the other n memory cells MC of the 2n memory cells MC arranged in each column.

In FIG. 2, the memory cell MC coupled to the word line WLi and the bit line BLAj is referred to as “MC1ᵢⱼ”, and the memory cell MC coupled to the word line WLi and the bit line BLBj is referred to as “MC2ᵢⱼ”. As shown in FIG. 2, the memory cell array 10 includes m×n memory cells MC1₁₁ to MC1ₘₙ and m×n memory cells MC2₁₁ to MC21ₘₙ. Each gate of the n memory cells MC1ᵢ₁ to MC1ᵢₙ and each gate of the n memory cells MC2ᵢ₁ to MC2ᵢₙ are coupled to the word line WLi. Each source of the n memory cells MC1ᵢ₁ to MC1ᵢₙ and each source of the n memory cells MC2ᵢ₁ to MC2ᵢₙ are coupled to the source line SLi. i is any integer from 1 to m. Each drain of the m memory cells MC1ᵢⱼ to MC1ₘⱼ is coupled to the bit line BLAj, and each drain of the m memory cells MC2ᵢⱼ to MC2ₘⱼ is coupled to the bit line BLBj. j is any integer from 1 to n. In the embodiment, the memory cell MC1ᵢⱼ and the memory cell MC2ᵢⱼ are complementary cells, one of which stores data “0” and the other stores data “1”.

As shown in FIG. 1, for example, a reference power supply potential VSS, a high power supply potential VPP for data erasing and data writing, and a logic power supply potential VDD for a logic circuit are externally supplied to the power supply circuit 20. Alternatively, the power supply circuit 20 may generate another power supply potential by stepping up or down one of a plurality of power supply potentials supplied from the outside.

The reference power supply potential VSS is a reference potential as a reference relative to other potentials, and a case where the reference power supply potential VSS is a ground potential will be described as below. The high power supply potential VPP is a predetermined potential higher than the reference power supply potential VSS, for example, about 5 V to 10 V. The logic power supply potential VDD is higher than the reference power supply potential VSS and lower than the high power supply potential VPP, for example, about 1.2 V to 1.8 V.

The power supply circuit 20 supplies the logic power supply potential VDD to the memory control circuit 80, and is controlled by the memory control circuit 80 to supply the high power supply potential VPP and the logic power supply potential VDD to each unit of the nonvolatile storage device 1 as necessary. In FIG. 1, the power supply potential supplied from the power supply circuit 20 to the word line booster circuit 30 is shown as a word line power supply potential VWL, and the power supply potential supplied from the power supply circuit 20 to the source line drive circuit 50 is shown as a source line power supply potential VSL.

In an erase mode in which data in the memory cell is erased and a write mode in which data is written in the memory cell, the power supply circuit 20 supplies the high power supply potential VPP to the word line booster circuit 30 and the source line drive circuit 50 as the word line power supply potential VWL and the source line power supply potential VSL. The word line booster circuit 30 supplies the high power supply potential VPP to the word line drive circuit 40 as a word line power supply potential INT_VWL.

In a read mode in which data of the memory cell is read out, the power supply circuit 20 supplies the logic power supply potential VDD to the word line booster circuit 30 and the source line drive circuit 50 as the word line power supply potential VWL and the source line power supply potential VSL. The word line booster circuit 30 generates a drive potential higher than the logic power supply potential VDD as the power supply potential on the high potential side supplied to the readout circuit 70, and supplies the drive potential to the word line drive circuit 40 as the word line power supply potential INT_VWL.

The word line drive circuit 40 drives the word line coupled to the memory cell MC selected by the memory control circuit 80 of the m word lines WL1 to WLm. The source line drive circuit 50 drives the source line coupled to the memory cell MC selected by the memory control circuit 80 of the m source lines SL1 to SLm.

In the read mode, the switch circuit 60 couples the bit line BLAk coupled to the memory cell MC selected by the memory control circuit 80 of the n bit lines BLA1 to BLAn to the bit line BLA, and couples the bit line BLBk coupled to the memory cell MC selected by the memory control circuit 80 of the n bit lines BLB1 to BLBn to the bit line BLB. k is an integer from 1 to n.

Specifically, as shown in FIG. 2, the switch circuit 60 includes n N-channel MOS transistors 61A-1 to 61A-n, n N-channel MOS transistors 61B-1 to 61B-n, an N-channel MOS transistor 62A, and an N-channel MOS transistor 62B. In FIG. 2, switch control signals SS1 to SSn, SSA, and SSB are signals supplied from the memory control circuit 80.

The switch control signal SSj is input to each gate of the MOS transistors 61A-j and 61B-j, and the switch control signals SS1 to SSn rise to high levels mutually exclusively. j is any integer from 1 to n. When the switch control signal SSj is at a low level, both of the MOS transistors 61A-j and 61B-j are turned into an OFF state in which the source and the drain are non-continuous, and when the switch control signal SSj is at a high level, both of the MOS transistors 61A-j and 61B-j are turned into an ON state in which the source and the drain are continuous.

The switch control signal SSA is input to the gate of the MOS transistor 62A. When the switch control signal SSA is at a low level, the MOS transistor 62A is turned into an OFF state in which the source and the drain are non-continuous, and when the switch control signal SSA is at a high level, the MOS transistor 62A is turned into an ON state in which the source and the drain are continuous.

The switch control signal SSB is input to the gate of the MOS transistor 62B. When the switch control signal SSB is at the low level, the MOS transistor 62B is turned into the OFF state in which the source and the drain are non-continuous, and when the switch control signal SSB is at the high level, the MOS transistor 62B is turned into the ON state in which the source and the drain are continuous.

For example, when both the switch control signal SSj and the switch control signal SSA are at the high level, both the MOS transistors 61A-j and 62A are turned on, and each drain of the m memory cells MC1ᵢⱼ to MC1ₘⱼ is coupled to the bit line BLA. Here, when the word line WLi and the source line SLi are selected, the drain and the source of the memory cell MC1ᵢⱼ are continuous, and a current flows from the bit line BLA to the source line SLi.

Similarly, when both the switch control signal SSj and the switch control signal SSB are at the high level, both of the MOS transistors 61B-j and 62B are turned on, and each drain of the m memory cells MC2₁ⱼ to MC2ₘⱼ is coupled to the bit line BLB. Here, when the word line WLi and the source line SLi are selected, the drain and the source of the memory cell MC2ᵢⱼ are continuous, and a current flows from the bit line BLB to the source line SLi.

Hereinafter, the memory cell MC1ᵢⱼ electrically coupled to the bit line BLA is referred to as “first memory cell”, and the current flowing through the memory cell MC1ᵢⱼ is referred to as “first detection current”. The memory cell MC2ᵢⱼ electrically coupled to the bit line BLB is referred to as “second memory cell”, and the current flowing through the memory cell MC2ᵢⱼ is referred to as “second detection current”.

As shown in FIG. 1, in the read mode, the readout circuit 70 outputs a data signal DQ according to the voltage of the bit line BLA and the voltage of the bit line BLB. Specifically, as shown in FIG. 2, the readout circuit 70 includes P-channel MOS transistors 71A, 71B, 73A, 73B, N-channel MOS transistors 74A, 74B, current sources 72A, 72B, and an output circuit 75. In FIG. 2, enable signals ENA and ENB are signals supplied from the memory control circuit 80.

The MOS transistor 71A has a gate and a drain coupled to a first node N1, and a source coupled to a VDD node as a power supply node to which the logic power supply potential VDD is supplied. The first node N1 is coupled to the bit line BLA. The MOS transistor 71B has a gate coupled to the gate of the MOS transistor 71A and the first node N1, a drain coupled to a second node N2, and a source coupled to the VDD node. The second node N2 is coupled to the bit line BLB.

For example, when all of the switch control signals SSj, SSA, and SSB are at the high level and the word line WLi and the source line SLi are selected, the first memory cell MC1ᵢⱼ is electrically coupled to the bit line BLA, and the second memory cell MC2ᵢⱼ is electrically coupled to the bit line BLB. Here, a current flows from the VDD node to a VSS node as a reference node to which the reference power supply potential VSS is supplied via the MOS transistor 71A and the memory cell MC1ᵢⱼ. That is, a first detection current ID1 flows through the memory cell MC1ᵢⱼ. Further, a current flows from the VDD node to the VSS node via the MOS transistor 71B and the memory cell MC2ᵢⱼ. That is, a second detection current ID2 flows through the memory cell MC2ᵢⱼ.

The current source 72A has one end coupled to the first node N1 and the other end coupled to the VSS node. The current source 72A is a current source that operates when the enable signal ENA is at a high level and causes a first reference current IR1 to flow from the first node N1 to the VSS node. The current source 72B has one end coupled to the second node N2 and the other end coupled to the VSS node. The current source 72B is a current source that operates when the enable signal ENB is at a high level and causes a second reference current IR2 to flow from the second node N2 to the VSS node. The first reference current IR1 and the second reference current IR2 are preferably equal. Here, “equal” is a concept including a case where a slight difference occurs due to a manufacturing error or the like.

The MOS transistor 73A has a gate coupled to the bit line BLA, a source coupled to the VDD node, and a drain coupled to a third node N3. The MOS transistor 74A has a gate coupled to the gate of the MOS transistor 74B and a fourth node N4, a source coupled to the VSS node, and a drain coupled to the third node N3.

The MOS transistor 73B has a gate coupled to the bit line BLB, a source coupled to the VDD node, and a drain coupled to the fourth node N4. The MOS transistor 74B has a gate and a drain coupled to the gate of the MOS transistor 74A and the fourth node N4, and the source coupled to the VSS node.

The output circuit 75 selects one of the third node N3 and the fourth node N4 as an output node, and outputs the data signal DQ at a low level or a high level. As below, a case where the third node N3 is selected as an output node will be described as an example. In the embodiment, when a voltage V1 of the first node N1 coupled to the bit line BLA is lower than a voltage V2 of the second node N2 coupled to the bit line BLB, a voltage V3 of the third node N3 becomes higher than a voltage V4 of the fourth node N4 and the output circuit 75 outputs a high-level data signal DQ. When the voltage V1 of the first node N1 is higher than the voltage V2 of the second node N2, the voltage V3 of the third node N3 becomes lower than the voltage V4 of the fourth node N4 and the output circuit 75 outputs a low-level data signal DQ. The high-level data signal DQ corresponds to data “1”, and the low-level data signal DQ corresponds to data “0”. In this manner, the readout circuit 70 reads out the data from the memory cell array 10 via the first node N1 and the second node N2.

The memory control circuit 80 includes, for example, a logic circuit or an analog circuit, to which a chip selection signal CS, a mode selection signal MS, a clock signal CK, and an address signal ADR are input from the outside of the nonvolatile storage device 1. Further, a read mode selection signal RMS is input from the register 90 to the memory control circuit 80.

When the nonvolatile storage device 1 is selected by the chip selection signal CS, the memory control circuit 80 sets the nonvolatile storage device 1 in the erase mode, the write mode, or the read mode according to the mode selection signal MS.

In the erase mode, the memory control circuit 80 controls each unit of the nonvolatile storage device 1 to erase the data of the plurality of memory cells MC designated by the address signal ADR in synchronization with the clock signal CK. For example, the data in the memory cell MC becomes “1” by data erasing. When m×n memory cells MC provided in the memory cell array 10 are divided into a plurality of sectors, in the erase mode, the memory control circuit 80 may collectively erase data of all memory cells MC provided in the sector designated by the address signal ADR.

In the write mode, write data WDT is input to the memory control circuit 80 from the outside, and the circuit controls each unit of the nonvolatile storage device 1 to write data of each bit of the write data WDT to the plurality of memory cells MC designated by the address signal ADR. For example, it is assumed that data of each of the plurality of memory cells MC to be written is “1” by data erasing or the like in advance, and data “0” is written in the necessary memory cell MC.

In the read mode, the memory control circuit 80 controls each unit of the nonvolatile storage device 1 to sequentially read data of the plurality of memory cells MC designated by the address signal ADR as data signals DQ. Then, the memory control circuit 80 reads out the data of the plurality of memory cells MC designated by the address signal ADR, and outputs data as read data RDT to the outside.

In the embodiment, the read mode includes a first mode and a second mode. In the first mode, the readout circuit 70 compares the first detection current ID1 with the second detection current ID2, and reads out complementary data for the first data stored in the first memory cell MC1ᵢⱼ and the second data stored in the second memory cell MC2ᵢⱼ. In the second mode, the readout circuit 70 compares a current obtained by addition of the first reference current IR1 to the first detection current ID1 with the second detection current ID2 and reads out complementary data, or compares the first detection current ID1 with a current obtained by addition of the second reference current IR2 to the second detection current ID2 and reads out complementary data.

The register 90 outputs the read mode selection signal RMS to the memory control circuit 80. The register 90 can be accessed from the outside of the nonvolatile storage device 1, and the read mode can be set to one of the first mode and the second mode from the outside. That is, the register 90 is a register that allows setting as to whether the readout circuit 70 is operated in the first mode or the second mode from outside.

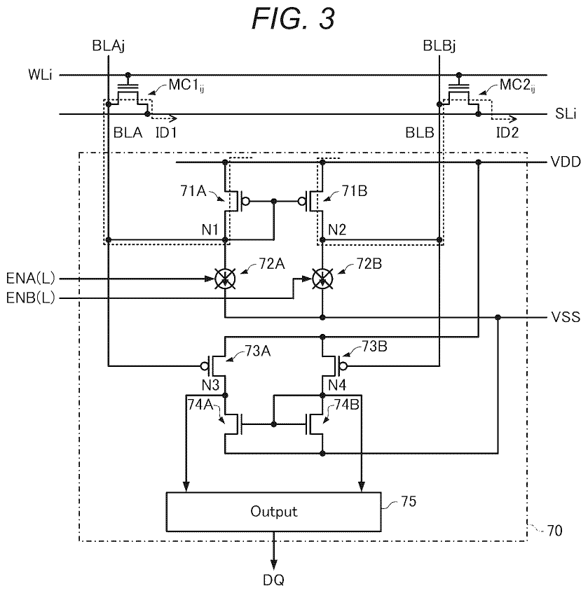

In the first mode, both of the enable signals ENA and ENB are at a low level. FIG. 3 shows a state of the readout circuit 70 when the read mode is set to the first mode. As shown in FIG. 3, in the first mode, since the enable signal ENA is at the low level and the current source 72A stops operating, the first reference current IR1 does not flow. Further, since the enable signal ENB is at the low level and the current source 72B stops operating, the second reference current IR2 does not flow.

In the example of FIG. 3, the first memory cell MC1ᵢⱼ is coupled to the bit line BLA, and thereby, the first detection current ID1 flows from the VDD node to the first memory cell MC1ᵢⱼ via the first node N1. Further, since the second memory cell MC2ᵢⱼ is coupled to the bit line BLB, the second detection current ID2 flows from the VDD node to the second memory cell MC2ᵢⱼ via the second node N2. The voltage V1 of the first node N1 coupled to the bit line BLA is determined according to the first detection current ID1, and the voltage V2 of the second node N2 coupled to the bit line BLB is determined according to the second detection current ID2.

The first memory cell MC1ᵢⱼ and the second memory cell MC2ᵢⱼ are complementary cells, and one of the first memory cell MC1ᵢⱼ and the second memory cell MC2ᵢⱼ stores complementary data as data “1” and the other stores complementary data as data “0”. When the first memory cell MC1ᵢⱼ stores data “1” and the second memory cell MC2ᵢⱼ stores data “0”, the first detection current ID1 is larger than the second detection current ID2. As a result, the voltage V1 of the first node N1 becomes lower than the voltage V2 of the second node N2, and the output circuit 75 outputs the high-level data signal DQ. On the other hand, when the first memory cell MC1ᵢⱼ stores data “0” and the second memory cell MC2ᵢⱼ stores data “1”, the first detection current ID1 is smaller than the second detection current ID2. As a result, the voltage V1 of the first node N1 becomes higher than the voltage V2 of the second node N2, and the output circuit 75 outputs the low-level data signal DQ.

As described above, in the first mode, the readout circuit 70 reads out the complementary data stored in the first memory cell MC1ᵢⱼ and the second memory cell MC2ᵢⱼ as the data signal DQ by comparing the first detection current ID1 flowing through the first memory cell MC1ᵢⱼ electrically coupled to the first node N1 with the second detection current ID2 flowing through the second memory cell MC2ᵢⱼ electrically coupled to the second node N2.

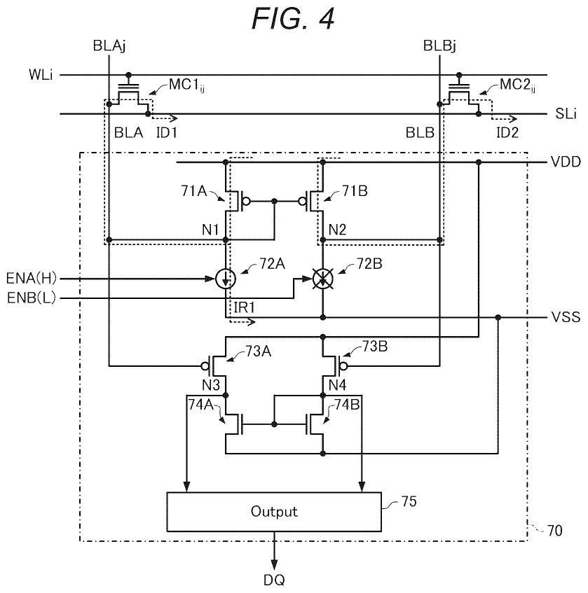

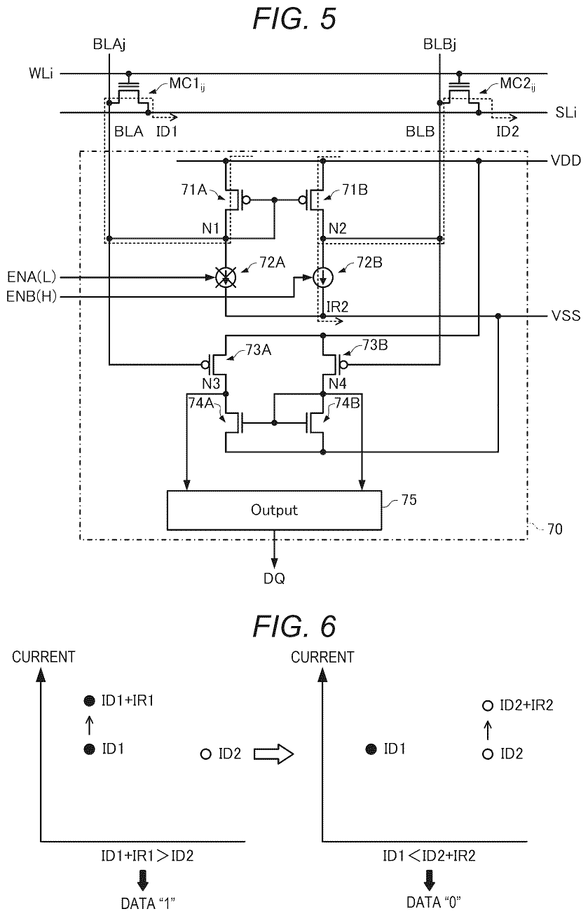

In the second mode, one of the enable signals ENA and ENB is at the low level, and the other is at the high level. FIGS. 4 and 5 show states of the readout circuit 70 when the read mode is set to the second mode. In the examples of FIGS. 4 and 5, like that in FIG. 3, the first detection current ID1 flows from the VDD node to the first memory cell MC1ᵢⱼ via the first node N1, and the second detection current ID2 flows from the VDD node to the second memory cell MC2ᵢⱼ via the second node N2. As shown in FIGS. 4 and 5, in the second mode, one of the current sources 72A and 72B operates, and the other stops operating.

In the example of FIG. 4, when the enable signal ENA is at the high level and the current source 72A operates, the first reference current IR1 flows. Accordingly, a current ID1+IR1 obtained by addition of the first reference current IR1 to the first detection current ID1 flows through the MOS transistor 71A. On the other hand, since the enable signal ENB is at the low level and the current source 72B stops operating, the second reference current IR2 does not flow, but the second detection current ID2 flows through the MOS transistor 71B. The voltage V1 of the first node N1 is determined according to the current ID1+IR1 flowing through the MOS transistor 71A, and the voltage V2 of the second node N2 is determined according to the second detection current ID2 flowing through the MOS transistor 71B.

When the first memory cell MC1ᵢⱼ stores data “1” and the second memory cell MC2ᵢⱼ stores data “0”, the first detection current ID1 is larger than the second detection current ID2. Accordingly, the current ID1+IR1 becomes larger than the second detection current ID2. As a result, the voltage V1 of the first node N1 becomes lower than the voltage V2 of the second node N2, and the output circuit 75 outputs the high-level data signal DQ. On the other hand, when the first memory cell MC1ᵢⱼ stores data “0” and the second memory cell MC2ᵢⱼ stores data “1”, the first detection current ID1 is smaller than the second detection current ID2. Here, when the difference between the first detection current ID1 and the second detection current ID2 is larger than the first reference current IR1, the current ID1+IR1 is smaller than the second detection current ID2. As a result, the voltage V1 of the first node N1 becomes higher than the voltage V2 of the second node N2, and the output circuit 75 outputs the low-level data signal DQ. When the difference between the first detection current ID1 and the second detection current ID2 is smaller than the first reference current IR1, the current ID1+IR1 is larger than the second detection current ID2. As a result, the voltage V1 of the first node N1 becomes lower than the voltage V2 of the second node N2, and the output circuit 75 outputs the high-level data signal DQ.

In the example of FIG. 5, since the enable signal ENA is at the low level and the current source 72A stops operating, the first reference current IR1 does not flow, but the first detection current ID1 flows through the MOS transistor 71A. On the other hand, since the enable signal ENB is at the high level and the current source 72B operates, the second reference current IR2 flows. Accordingly, a current ID2+IR2 obtained by addition of the second reference current IR2 to the second detection current ID2 flows through the MOS transistor 71B. The voltage V1 of the first node N1 is determined according to the first detection current ID1 flowing through the MOS transistor 71A, and the voltage V2 of the second node N2 is determined according to the current ID2+IR2 flowing through the MOS transistor 71B.

When the first memory cell MC1ᵢⱼ stores data “1” and the second memory cell MC2ᵢⱼ stores data “0”, the first detection current ID1 is larger than the second detection current ID2. Here, when the difference between the first detection current ID1 and the second detection current ID2 is larger than the second reference current IR2, the first detection current ID1 is larger than the current ID2+IR2. As a result, the voltage V1 of the first node N1 becomes lower than the voltage V2 of the second node N2, and the output circuit 75 outputs the high-level data signal DQ. When the difference between the first detection current ID1 and the second detection current ID2 is smaller than the second reference current IR2, the first detection current ID1 is smaller than the current ID2+IR2. As a result, the voltage V1 of the first node N1 becomes higher than the voltage V2 of the second node N2, and the output circuit 75 outputs the low-level data signal DQ. On the other hand, when the first memory cell MC1ᵢⱼ stores data “0” and the second memory cell MC2ᵢⱼ stores data “1”, the first detection current ID1 is smaller than the second detection current ID2. Accordingly, the first detection current ID1 is smaller than the current ID2+IR2. As a result, the voltage V1 of the first node N1 becomes higher than the voltage V2 of the second node N2, and the output circuit 75 outputs the low-level data signal DQ.

As described above, in the second mode, the readout circuit 70 reads out the complementary data stored in the first memory cell MC1ᵢⱼ and the second memory cell MC2ᵢⱼ as the data signal DQ by comparing the current ID1+IR1 obtained by addition of the first reference current IR1 to the first detection current ID1 flowing through the first memory cell MC1ᵢⱼ electrically coupled to the first node N1 with the second detection current ID2 flowing through the second memory cell MC2ᵢⱼ electrically coupled to the second node N2. Or, in the second mode, the readout circuit 70 reads out the complementary data stored in the first memory cell MC1ᵢⱼ and the second memory cell MC2ᵢⱼ as the data signal DQ by comparing the first detection current ID1 flowing through the first memory cell MC1ᵢⱼ electrically coupled to the first node N1 with the current ID2+IR2 obtained by addition of the second reference current IR2 to the second detection current ID2 flowing through the second memory cell MC2ᵢⱼ electrically coupled to the second node N2.

The data reading in the second mode can be used, for example, for verification after writing of the complementary data in the first memory cell MC1ᵢⱼ and the second memory cell MC2ᵢⱼ and, when the data stored in the first memory cell MC1ᵢⱼ and the second memory cell MC2ᵢⱼ is regarded as the complementary data in the initial state, for checking whether the initial value of the complementary data is “1”, “0”, or indeterminate.

Specifically, the readout circuit 70 first adds the first reference current IR1 to the first detection current ID1 to read out the complementary data, and then, adds the second reference current IR2 to the second detection current ID2 to read the complementary data. When the read two pieces of complementary data are not coincident, a margin for a determination threshold between data “1” and data “0” is insufficient. For example, as shown in FIG. 6, when the difference between the first detection current ID1 and the second detection current ID2 is smaller, the data obtained by addition of the first reference current IR1 to the first detection current ID1 and read out is “1” and the data obtained by addition of the second reference current IR2 to the second detection current ID2 and read out is “0”. The two pieces of complementary data are not coincident. For example, when the two pieces of complementary data are not coincident in the verification after writing of the complementary data, the writing is performed again. Further, in the check of the initial value of the complementary data, the data is determined as being indeterminate.

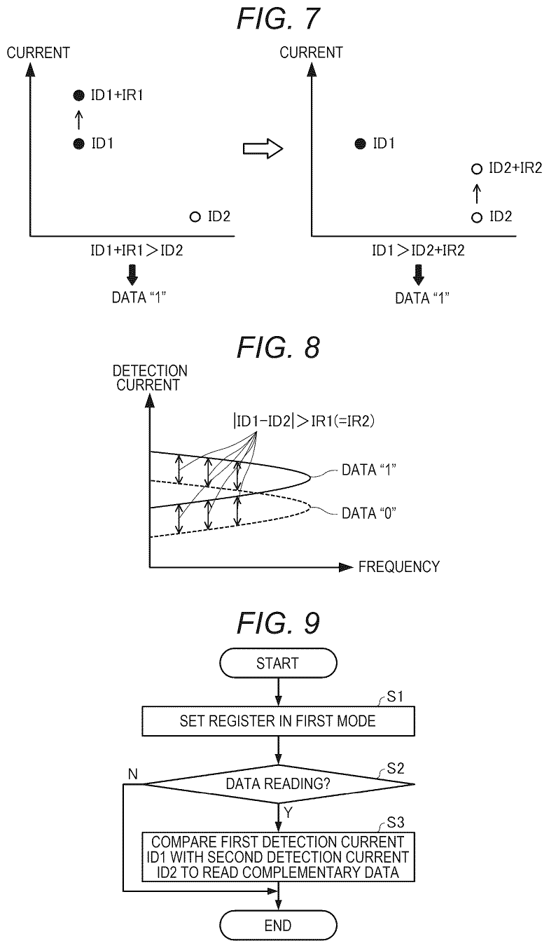

On the other hand, when the read two pieces of complementary data are coincident, the margin for the determination threshold between data “1” and data “0” is sufficient. For example, as shown in FIG. 7, when the difference between the first detection current ID1 and the second detection current ID2 is larger, the data obtained by addition of the first reference current IR1 to the first detection current ID1 and read out is “1” and the data obtained by addition of the second reference current IR2 to the second detection current ID2 and read out is “1”. The two pieces of complementary data are coincident. For example, when the two pieces of complementary data are coincident in verification after writing of the complementary data, re-writing is unnecessary. In the check of the initial value of the complementary data, a determination that the data is “1” or “0” is made.

Here, it is assumed that the first reference current IR1 and the second reference current IR2 are equal, and data “1” is written in one of the first memory cell MC1ᵢⱼ and the second memory cell MC2ᵢⱼ as the complementary cells, and data “0” is written in the other. In this case, when the difference between the first detection current ID1 and the second detection current ID2 is larger than the first reference current IR1 (=second reference current IR2) false reading of complementary data does not occur. That is, as long as the difference between the first detection current ID1 and the second detection current ID2 may be larger than the first reference current IR1 (=second reference current IR2) with respect to the first memory cell MC1ᵢⱼ and the second memory cell MC2ᵢⱼ forming a pair, a distribution of the detection current flowing in each memory storing the data “1” and a distribution of the detection current flowing in each memory storing the data “0” may partially overlap as shown in FIG. 8. Accordingly, in the embodiment, it is not necessary to assume an excessive margin in the difference between the first detection current ID1 and the second detection current ID2 and the writing time can be shortened as compared with writing in related art in which the distribution of the detection current flowing in each memory storing the data “1” and the distribution of the detection current flowing in each memory storing the data “0” are distributed not to vertically overlap with each other with the reference current as a boundary. Therefore, it is not necessary to apply excessive stress to each memory cell MC, and deterioration of each memory cell MC is reduced.

FIG. 9 is a flowchart showing an example of a procedure of data reading in the first mode. In the example of FIG. 9, first, at step S1, the first mode is set in the register 90 by an external device of the nonvolatile storage device 1. Then, at step S2, when data reading is requested from the external device, at step S3, the readout circuit 70 compares the first detection current ID1 with the second detection current ID2 and reads out the complementary data. Then, the external device acquires the read data RDT containing the complementary data output from the nonvolatile storage device 1.

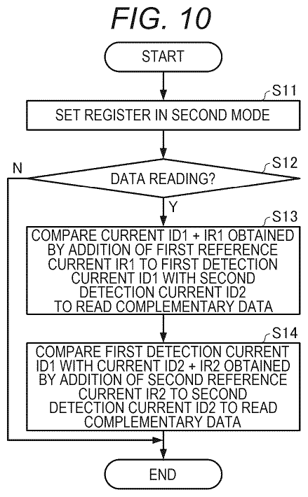

FIG. 10 is a flowchart showing an example of a procedure of data reading in the second mode. In the example of FIG. 10, first, at step S11, the second mode is set in the register 90 by the external device of the nonvolatile storage device 1. Then, at step S12, when data reading is requested from the external device, at step S13, the readout circuit 70 compares the current ID1+IR1 obtained by addition of the first reference current IR1 to the first detection current ID1 with the second detection current ID2 and reads out the complementary data. Then, the external device acquires the read data RDT containing the complementary data output from the nonvolatile storage device 1. Further, at step S14, the readout circuit 70 compares the first detection current ID1 with the current ID2+IR2 obtained by addition of the second reference current IR2 to the second detection current ID2 and reads out the complementary data. Then, the external device acquires the read data RDT containing the complementary data output from the nonvolatile storage device 1. The external device can determine that the difference between the first detection current ID1 and the second detection current ID2 is sufficient when the two pieces of complementary data contained in the acquired two pieces of read data RDT are coincident, and can determine that the difference between the first detection current ID1 and the second detection current ID2 is insufficient when the two pieces of complementary data are not coincident.

In the above described nonvolatile storage device 1 of the first embodiment, the readout circuit 70 can read out the complementary data stored in the first memory cell MC1ᵢⱼ and the second memory cell MC2ᵢⱼ by comparing the current ID1+IR1 obtained by addition of the first reference current IR1 to the first detection current ID1 with the second detection current ID2 in the second mode, and can read out the complementary data by comparing the first detection current ID1 with the current ID2+IR2 obtained by addition of the second reference current IR2 to the second detection current ID2.

For example, in verification after complementary data is written in the first memory cell MC1ᵢⱼ and the second memory cell MC2ᵢⱼ, the external device may determine whether the two pieces of complementary data read out in the second mode are coincident, repeat writing of the complementary data until the two pieces of complementary data are coincident, and end writing when the difference between the first detection current ID1 and the second detection current ID2 is larger than the first reference current IR1 and the second reference current IR2. Therefore, according to the nonvolatile storage device 1 of the first embodiment, it is not necessary to increase the difference between the first detection current ID1 and the second detection current ID2 more than necessary and the write time can be shortened. Further, stress due to application of a high voltage at writing may be reduced and acceleration of deterioration of the first memory cell MC1ᵢⱼ and the second memory cell MC2ᵢⱼ may be reduced.

For example, in the initial state of the nonvolatile storage device 1, the external device can determine whether the initial value of the data stored in the first memory cell MC1ᵢⱼ and the second memory cell MC2ᵢⱼ is “0”, “1”, or indeterminate based on the two pieces of complementary data read out in the second mode.

In addition, according to the nonvolatile storage device 1 of the first embodiment, the external device can optionally select whether to read out complementary data in the first mode or the second mode, and thereby, versatility can be enhanced.

### 1-2. Second Embodiment

As below, regarding a nonvolatile storage device 1 according to a second embodiment, the same configurations as those of the first embodiment will have the same signs and the same descriptions as those of the first embodiment will be omitted or simplified, and the configurations different from those of the first embodiment will be mainly described.

A block diagram showing a schematic configuration of the nonvolatile storage device 1 of the second embodiment is the same as FIG. 1, and the illustration and the description thereof are omitted. Further, the detailed configurations of the memory cell array 10, the switch circuit 60, and the readout circuit 70 according to the second embodiment are the same as those in FIG. 2, and the illustration and the description thereof are omitted.

In the second embodiment, the register 90 can set the read mode to the first mode. Data reading in the first mode is the same as that in the first embodiment.

In the second embodiment, the register 90 can set the read mode to the second mode. When the register 90 is set to the second mode, the readout circuit 70 performs data reading in the second mode only once based on write data in verification after data writing. Specifically, the readout circuit 70 determines whether to add the first reference current IR1 to the first detection current ID1 or add the second reference current IR2 to the second detection current ID2 based on the complementary data written in the first memory cell MC1ᵢⱼ and the second memory cell MC2ᵢⱼ, and reads out the complementary data in the second mode. For example, when the first data “0” is written in the first memory cell MC1ᵢⱼ and the second data “1” is written in the second memory cell MC2ᵢⱼ, the readout circuit 70 reads out the complementary data stored in the first memory cell MC1ᵢⱼ and the second memory cell MC2ᵢⱼ as a data signal DQ by comparing the current ID1+IR1 obtained by addition of the first reference current IR1 to the first detection current ID1 with the second detection current ID2 in the second mode. On the other hand, when the first data “1” is written in the first memory cell MC1ᵢⱼ and the second data “0” is written in the second memory cell MC2ᵢⱼ, the readout circuit 70 reads out the complementary data stored in the first memory cell MC1ᵢⱼ and the second memory cell MC2ᵢⱼ as a data signal DQ by comparing the first detection current ID1 with the current ID2+IR2 obtained by addition of the second reference current IR2 to the second detection current ID2 in the second mode. In the verification after writing of the complementary data, when the written complementary data and the read complementary data are not coincident, writing is performed again.

In the second embodiment, the register 90 can set the read mode to both the first mode and the second mode. When the register 90 is set to both the first mode and the second mode, the readout circuit 70 first performs data reading in the first mode, and further performs data reading in the second mode only once based on the read complementary data. Specifically, the readout circuit 70 reads the complementary data stored in the first memory cell MC1ᵢⱼ and the second memory cell MC2ᵢⱼ in the first mode, determines whether to add the first reference current IR1 to the first detection current ID1 or add the second reference current IR2 to the second detection current ID2 based on the complementary data read out in the first mode, and reads out the complementary data in the second mode. For example, when the data “0” is read out in the first mode, the readout circuit 70 reads out the complementary data stored in the first memory cell MC1ᵢⱼ and the second memory cell MC2ᵢⱼ as a data signal DQ by comparing the current ID1+IR1 obtained by addition of the first reference current IR1 to the first detection current ID1 with the second detection current ID2 in the second mode. When reading data “1” in the first mode, the readout circuit 70 reads out the complementary data stored in the first memory cell MC1ᵢⱼ and the second memory cell MC2ᵢⱼ as a data signal DQ by comparing the current ID1 with the current ID2+IR2 obtained by addition of the second reference current IR2 to the second detection current ID2 in the second mode.

The data reading in the first mode and the second mode can be used for checking that the initial value of the complementary data is “1”, “0”, or indeterminate when the data stored in the first memory cell MC1ᵢⱼ and the second memory cell MC2ᵢⱼ is regarded as the complementary data in the initial state.

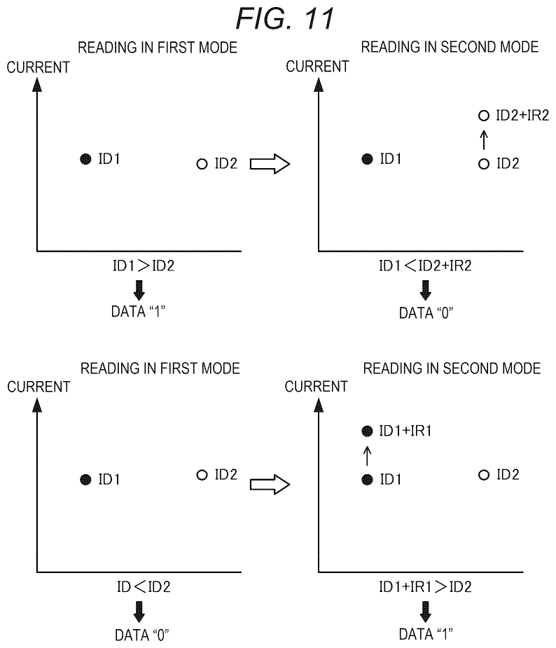

Specifically, when the complementary data read out in the first mode and the complementary data read out in the second mode are not coincident, a margin for a determination threshold between data “1” and data “0” is insufficient. For example, as shown in the upper part of FIG. 11, when the difference between the first detection current ID1 and the second detection current ID2 is smaller, the data read out in the first mode is “1”, whereas the data read out with the addition of the second reference current IR2 to the second detection current ID2 in the second mode is “0”. The two pieces of data are not coincident. Further, for example, as shown in the lower part of FIG. 11, when the difference between the second detection current ID2 and the first detection current ID1 is smaller, the data read out in the first mode is “0”, whereas the data read out with the addition of the first reference current IR1 to the first detection current ID1 in the second mode is “1”. The two pieces of data are not coincident. Accordingly, in these cases, a determination that the data is indeterminate is made.

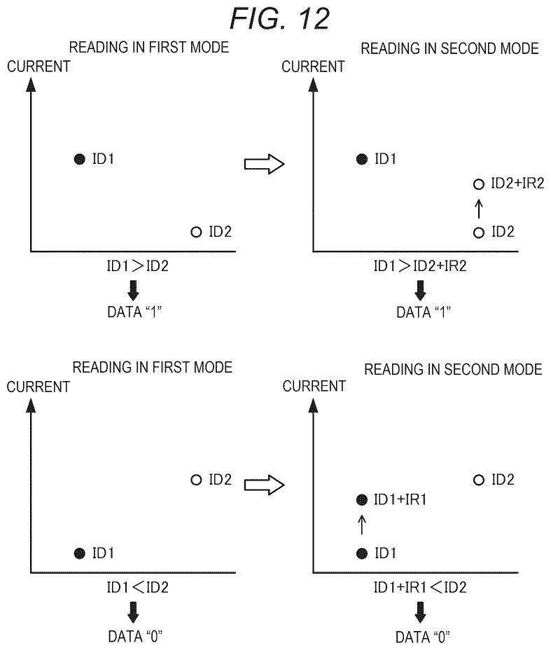

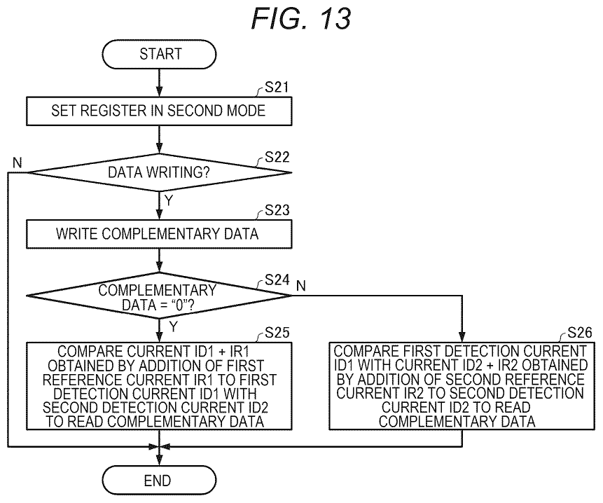

On the other hand, when the complementary data read out in the first mode and the complementary data read out in the second mode are coincident, the margin for the determination threshold between data “1” and data “0” is sufficient. For example, as shown in the upper part of FIG. 12, when the difference between the first detection current ID1 and the second detection current ID2 is larger, the data read out in the first mode is “1”, whereas the data read out with the addition of the second reference current IR2 to the second detection current ID2 in the second mode is “1”. The two pieces of data are coincident. Accordingly, in this case, the data is determined as “1”. Further, for example, as shown in the lower part of FIG. 12, when the difference between the second detection current ID2 and the first detection current ID1 is larger, the data read out in the first mode is “0”, whereas the data read out with the addition of the first reference current IR1 to the first detection current ID1 in the second mode is “0”. The two pieces of data are coincident. Accordingly, in this case, the data is determined as “0”.

FIG. 13 is a flowchart showing an example of a verification procedure of data writing and data reading in the second mode. In the example of FIG. 13, first, at step S21, the second mode is set in the register 90 by the external device of the nonvolatile storage device 1. Then, at step S22, when data writing is requested from the external device, at step S23, complementary data is written.

Then, at step S24, when the complementary data written at step S23 is “0”, at step S25, the readout circuit 70 compares the current ID1+IR1 obtained by addition of the first reference current IR1 to the first detection current ID1 with the second detection current ID2 and reads the complementary data in the second mode. Then, the external device acquires the read data RDT containing the complementary data output from the nonvolatile storage device 1. On the other hand, at step S24, when the complementary data written at step S23 is “1”, at step S26, the readout circuit 70 compares the first detection current ID1 with the current ID2+IR2 obtained by addition of the second reference current IR2 to the second detection current ID2 and reads the complementary data. Then, the external device acquires the read data RDT containing the complementary data output from the nonvolatile storage device 1. The external device can determine that the difference between the first detection current ID1 and the second detection current ID2 is sufficient when the complementary data contained in the write data WDT and the complementary data contained in the acquired read data RDT are coincident and, can determine that the difference between the first detection current ID1 and the second detection current ID2 is insufficient and write data again when the two pieces of complementary data are not coincident.

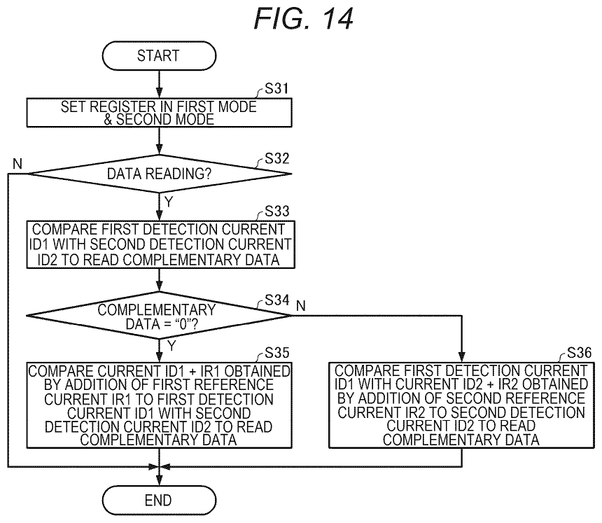

FIG. 14 is a flowchart showing an example of a procedure of data reading in the first mode and the second mode. In the example of FIG. 14, first, at step S31, the first mode and the second mode are set in the register 90 by the external device of the nonvolatile storage device 1. Then, at step S32, data reading is requested from the external device, at step S33, the readout circuit 70 compares the first detection current ID1 with the second detection current ID2 and reads out the complementary data in the first mode. Then, the external device acquires the read data RDT containing the complementary data output from the nonvolatile storage device 1.

Next, at step S34, when the complementary data read out at step S33 is “0”, at step S35, the readout circuit 70 compares the current ID1+IR1 obtained by addition of the first reference current IR1 to the first detection current ID1 with the second detection current ID2 and reads out the complementary data in the second mode. Then, the external device acquires the read data RDT containing the complementary data output from the nonvolatile storage device 1. On the other hand, at step S34, when the complementary data read out at step S33 is “1”, at step S36, the readout circuit 70 compares the first detection current ID1 with the current ID2+IR2 obtained by addition of the second reference current IR2 to the second detection current ID2 and reads out the complementary data. Then, the external device acquires the read data RDT containing the complementary data output from the nonvolatile storage device 1. The external device can determine that the difference between the first detection current ID1 and the second detection current ID2 is sufficient when the two pieces of complementary data contained in the acquired two pieces of read data RDT are coincident, and can determine that the difference between the first detection current ID1 and the second detection current ID2 is insufficient when the two pieces of complementary data are not coincident.

The other configurations and functions of the nonvolatile storage device 1 of the second embodiment are the same as those of the first embodiment, and thus the description thereof is omitted.

According to the above described nonvolatile storage device 1 of the second embodiment, the same effects as those of the nonvolatile storage device 1 of the first embodiment can be obtained.

Further, according to the nonvolatile storage device 1 of the second embodiment, the readout circuit 70 continuously performs reading of the complementary data in the first mode and reading of the complementary data in the second mode in response to a command from the external device, and thereby, the processing load of the external device may be reduced compared to a case where the external device commands reading of the complementary data in the first mode and further commands reading of the complementary data in the second mode.

Furthermore, according to the nonvolatile storage device 1 of the second embodiment, since it is only necessary that the readout circuit 70 performs reading in the second mode once for verification after writing of complementary data, the time required for the verification is shortened. In addition, according to the nonvolatile storage device 1 of the second embodiment, the readout circuit 70 performs data reading for verification after writing in response to a write command from the external device, and thereby, the processing load of the external device may be reduced compared to a case where the external device commands writing and further commands data reading for verification after the writing.

### 1-3. Third Embodiment

As below, regarding the nonvolatile storage device 1 of the third embodiment, the same configurations as those of the first embodiment or the second embodiment will have the same signs and the same descriptions as those of the first embodiment or the second embodiment will be omitted or simplified, and the configurations different from those of the first embodiment and the second embodiment will be mainly described.

A block diagram showing a schematic configuration of the nonvolatile storage device 1 of the third embodiment is the same as FIG. 1, and the illustration and the description thereof are omitted. The detailed configurations of the memory cell array 10, the switch circuit 60, and the readout circuit 70 in the third embodiment are the same as those in FIG. 2, and the illustration and the description thereof are omitted.

In the third embodiment, the register 90 can set the read mode to the first mode. Data reading in the first mode is the same as that in the first embodiment. Further, in the third embodiment, the register 90 can set the read mode to the second mode. Data reading in the second mode is the same as that in the first embodiment or the second embodiment. Or, in the third embodiment, the register 90 may set the read mode to the first mode and the second mode. Data reading in the first mode and the second mode is the same as that in the second embodiment.

Furthermore, in the third embodiment, the register 90 can set the read mode to a third mode.

In the third mode, the readout circuit 70 compares the first detection current ID1 with the second reference current IR2 to read out data stored in the first memory cell MC1ᵢⱼ, or compares the second detection current ID2 with the first reference current IR1 to read out data stored in the second memory cell MC2ᵢⱼ.

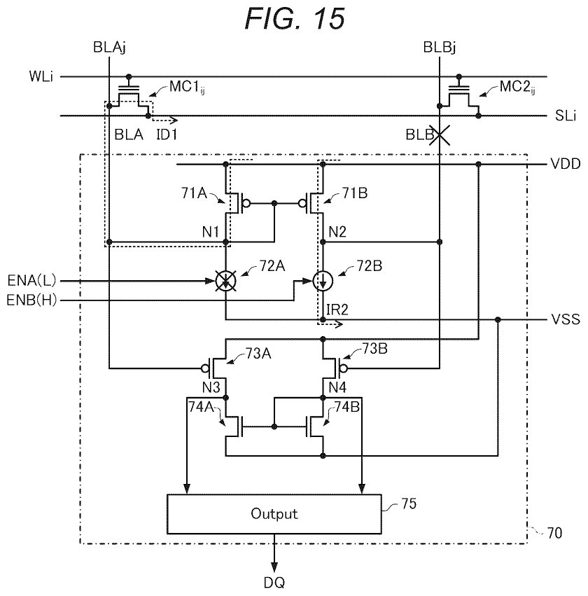

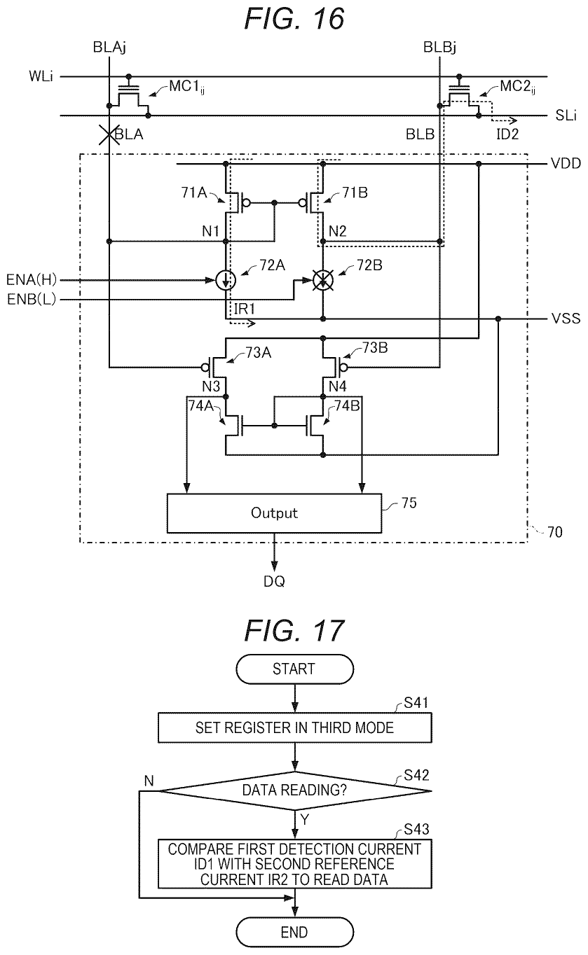

In the third mode, the switch control signal SSA and the enable signal ENB are at a high level, the switch control signal SSB and the enable signal ENA are at a low level, and the data stored in the first memory cells MC1ᵢⱼ is read out. Alternatively, the switch control signal SSB and the enable signal ENA are at the high level, the switch control signal SSA and the enable signal ENB are at the low level, and the data stored in the second memory cells MC2ᵢⱼ is read out. Further, in the third mode, when the data stored in the first memory cell MC1ᵢⱼ is read out, the output circuit 75 selects the third node N3 as an output node, and when the data stored in the second memory cell MC2ᵢⱼ is read out, the output circuit 75 selects the fourth node N4 as an output node. FIGS. 15 and 16 show states of the readout circuit 70 when the read mode is set to the third mode.

In the example of FIG. 15, the first detection current ID1 flows from the VDD node to the first memory cell MC1ᵢⱼ via the first node N1, but the second detection current ID2 does not flow to the second memory cell MC2ᵢⱼ. Since the enable signal ENA is at the low level and the current source 72A stops operating, the first reference current IR1 does not flow, but the first detection current ID1 flows through the MOS transistor 71A. On the other hand, since the enable signal ENB is at the high level and the current source 72B operates, the second reference current IR2 flows through the MOS transistor 71B. Then, the voltage V1 of the first node N1 is determined according to the first detection current ID1 flowing through the MOS transistor 71A, and the voltage V2 of the second node N2 is determined according to the second reference current IR2 flowing through the MOS transistor 71B.

When the first memory cell MC1ᵢⱼ stores data “1”, the first detection current ID1 is larger than the second reference current IR2. As a result, the voltage V1 of the first node N1 becomes lower than the voltage V2 of the second node N2, and the output circuit 75 outputs a high-level data signal DQ. On the other hand, when the first memory cell MC1ᵢⱼ stores data “0”, the first detection current ID1 is smaller than the second reference current IR2. As a result, the voltage V1 of the first node N1 becomes higher than the voltage V2 of the second node N2, and the output circuit 75 outputs a low-level data signal DQ.

In the example of FIG. 16, the second detection current ID2 flows from the VDD node to the second memory cell MC2ᵢⱼ via the second node N2, but the first detection current ID1 does not flow to the first memory cell MC1ᵢⱼ. Since the enable signal ENB is at the low level and the current source 72B stops operating, the second reference current IR2 does not flow, but the second detection current ID2 flows through the MOS transistor 71B. On the other hand, since the enable signal ENA is at the high level and the current source 72A operates, the first reference current IR1 flows through the MOS transistor 71A. Then, the voltage V2 of the second node N2 is determined according to the second detection current ID2 flowing through the MOS transistor 71B, and the voltage V1 of the first node N1 is determined according to the first reference current IR1 flowing through the MOS transistor 71A.

When the second memory cell MC2ᵢⱼ stores data “1”, the second detection current ID2 is larger than the first reference current IR1. As a result, the voltage V2 of the second node N2 becomes lower than the voltage V1 of the first node N1, and the output circuit 75 outputs the high-level data signal DQ. On the other hand, when the second memory cell MC2ᵢⱼ stores data “0”, the second detection current ID2 is smaller than the first reference current IR1. As a result, the voltage V2 of the second node N2 becomes higher than the voltage V1 of the first node N1, and the output circuit 75 outputs the low-level data signal DQ.

As described above, in the third embodiment, the register 90 can set the read mode to the third mode. That is, in the third embodiment, the register 90 is a register that allows setting as to whether the readout circuit 70 is operated in the first mode, the second mode, or the third mode from outside.

In the embodiment, the first memory cell MC1ᵢⱼ and the second memory cell MC2ᵢⱼ may store complementary data as a pair, or each may store data alone. In the former case, the pieces of complementary data stored in the first memory cell MC1ᵢⱼ and the second memory cell MC2ᵢⱼ are read out in the first mode and, in the latter case, the data stored in each of the first memory cell MC1ᵢⱼ and the second memory cell MC2ᵢⱼ is read out in the third mode.

The plurality of memory cells MC provided in the memory cell array 10 may be divided into a plurality of groups, and whether data is read out in the first mode or the third mode may be set in the register 90 for each group. For example, two of memory cells MC contained in the first group may store complementary data as pairs, and each memory cell MC contained in the second group may store data alone. In this case, the readout circuit 70 may read out complementary data in the first mode from the pairs of memory cells MC of the first group and read out data in the third mode from each memory cell MC of the second group. The plurality of memory cells MC provided in the memory cell array 10 may be divided into one group for each sector.

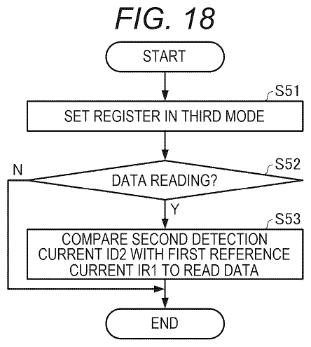

FIGS. 17 and 18 are flowcharts showing an example of a procedure of data reading in the third mode.

FIG. 17 shows a procedure for reading data stored in the first memory cell MC1ᵢⱼ. In the example of FIG. 17, first, at step S41, the third mode is set in the register 90 by the external device of the nonvolatile storage device 1. Then, at step S42, when data reading is requested from the external device, at step S43, the readout circuit 70 compares the first detection current ID1 with the second reference current IR2 and reads out data. Then, the external device acquires the read data RDT containing the data output from the nonvolatile storage device 1.

FIG. 18 shows a procedure for reading data stored in the second memory cell MC2ᵢⱼ. In the example of FIG. 18, first, at step S51, the third mode is set in the register 90 by the external device of the nonvolatile storage device 1. Then, at step S52, when data reading is requested from the external device, at step S53, the readout circuit 70 compares the second detection current ID2 with the first reference current IR1 and reads out data. Then, the external device acquires the read data RDT containing the data output from the nonvolatile storage device 1.

The other configurations and functions of the nonvolatile storage device 1 of the third embodiment are the same as those of the first embodiment or the second embodiment, and thus the description thereof will be omitted.

According to the above described nonvolatile storage device 1 of the third embodiment, the same effects as those of the nonvolatile storage device 1 of the first embodiment or the second embodiment can be obtained. Further, according to the nonvolatile storage device 1 of the third embodiment, the external device can write, not complementary data, but independent single data in the first memory cell MC1ᵢⱼ and the second memory cell MC2ᵢⱼ, and respectively read out the two pieces of single data in the third mode. That is, according to the nonvolatile storage device 1 of the third embodiment, whether the complementary data or the single data is stored in each memory cell MC can be selected, and the external device can versatility use the memory cell array 10 for many purposes. For example, when a plurality of different types of data are stored in the memory cell array 10, whether to store complementary data or single data is appropriately selected according to the characteristics of each data, and thereby, the use efficiency of the memory cell array 10 can be increased.

Furthermore, according to the nonvolatile storage device 1 of the third embodiment, the external device can optionally select whether to read out data in the first mode, the second mode, or the third mode, and thereby, versatility can be enhanced.

### 1-4. Fourth Embodiment

As below, regarding a nonvolatile storage device 1 of a fourth embodiment, the same configurations as those of the first embodiment to the third embodiment will have the same signs and the same descriptions as those of the first embodiment to the third embodiment will be omitted or simplified, and the configurations different from those of the first embodiment to the third embodiment will be mainly described.

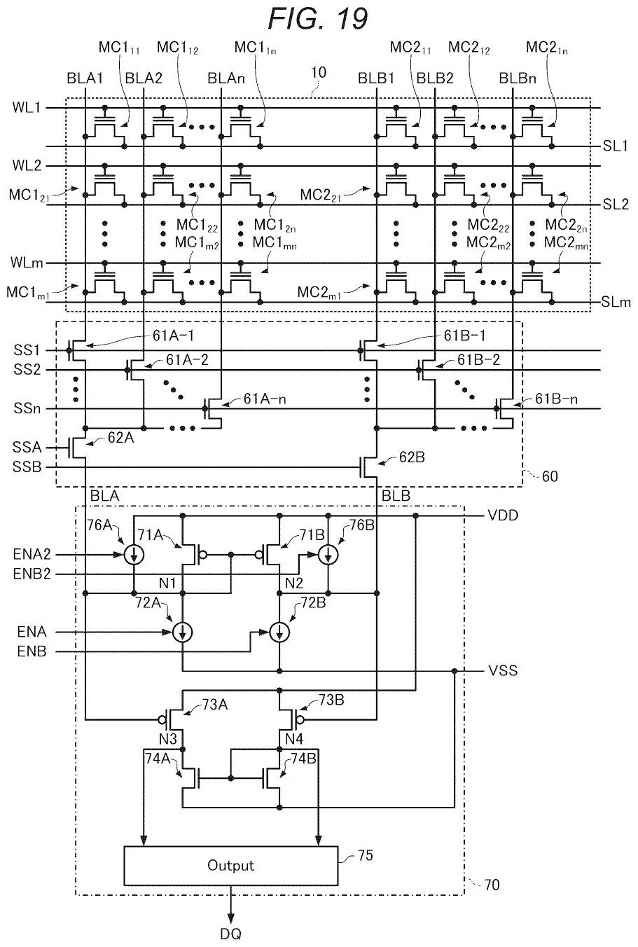

A block diagram showing a schematic configuration of the nonvolatile storage device 1 of the fourth embodiment is the same as FIG. 1, and the illustration and the description thereof are omitted. FIG. 19 shows a detailed configuration example of the memory cell array 10, the switch circuit 60, and the readout circuit 70 in the fourth embodiment. Since the configurations of the memory cell array 10 and the switch circuit 60 are the same as those in FIG. 2, the description thereof will be omitted.

As shown in FIG. 19, the readout circuit 70 in the fourth embodiment is different from the readout circuit 70 in the first embodiment to the third embodiment shown in FIG. 2 in that current sources 76A and 76B are added.

The current source 76A has one end coupled to the VDD node and the other end coupled to the first node N1. The current source 76A is a current source that operates when an enable signal ENA2 is at a high level and causes the first reference current IR1 to flow from the VDD node to the first node N1. The current source 76B has one end coupled to the VDD node and the other end coupled to the second node N2. The current source 76B is a current source that operates when an enable signal ENB2 is at a high level and causes the second reference current IR2 to flow from the VDD node to the second node N2. The enable signals ENA2 and ENB2 are signals supplied from the memory control circuit 80. The first reference current IR1 and the second reference current IR2 are preferably equal. Here, “equal” is a concept including a case where a slight difference occurs due to a manufacturing error or the like.

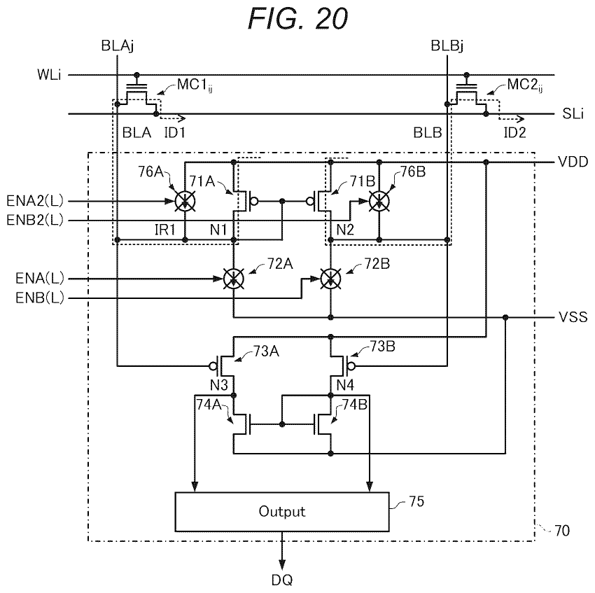

In the first mode, all of the enable signals ENA, ENB, ENA2, and ENB2 are at the low level. FIG. 20 shows a state of the readout circuit 70 when the read mode is set to the first mode. As shown in FIG. 20, in the first mode, since the enable signal ENA is at the low level and the current source 72A stops operating, the first reference current IR1 does not flow. Further, since the enable signal ENB is at the low level and the current source 72B stops operating, the second reference current IR2 does not flow.

In the example of FIG. 20, since the first memory cell MC1ᵢⱼ is coupled to the bit line BLA, the first detection current ID1 flows from the VDD node to the first memory cell MC1ᵢⱼ via the first node N1. Further, since the second memory cell MC2ᵢⱼ is coupled to the bit line BLB, the second detection current ID2 flows from the VDD node to the second memory cell MC2ᵢⱼ via the second node N2. The voltage V1 of the first node N1 is determined according to the first detection current ID1, and the voltage V2 of the second node N2 is determined according to the second detection current ID2.

The first memory cell MC1ᵢⱼ and the second memory cell MC2ᵢⱼ are complementary cells, and one of the first memory cell MC1ᵢⱼ and the second memory cell MC2ᵢⱼ stores complementary data as data “1” and the other stores complementary data as data “0”. When the first memory cell MC1ᵢⱼ stores data “1” and the second memory cell MC2ᵢⱼ stores data “0”, the first detection current ID1 is larger than the second detection current ID2. As a result, the voltage V1 of the first node N1 becomes lower than the voltage V2 of the second node N2, and the output circuit 75 outputs a high-level data signal DQ. On the other hand, when the first memory cell MC1ᵢⱼ stores data “0” and the second memory cell MC2ᵢⱼ stores data “1”, the first detection current ID1 is smaller than the second detection current ID2. As a result, the voltage V1 of the first node N1 becomes higher than the voltage V2 of the second node N2, and the output circuit 75 outputs a low-level data signal DQ.

As described above, in the first mode, the readout circuit 70 reads out the complementary data stored in the first memory cell MC1ᵢⱼ and the second memory cell MC2ᵢⱼ as the data signal DQ by comparing the first detection current ID1 flowing through the first memory cell MC1ᵢⱼ electrically coupled to the first node N1 with the second detection current ID2 flowing through the second memory cell MC2ᵢⱼ electrically coupled to the second node N2.

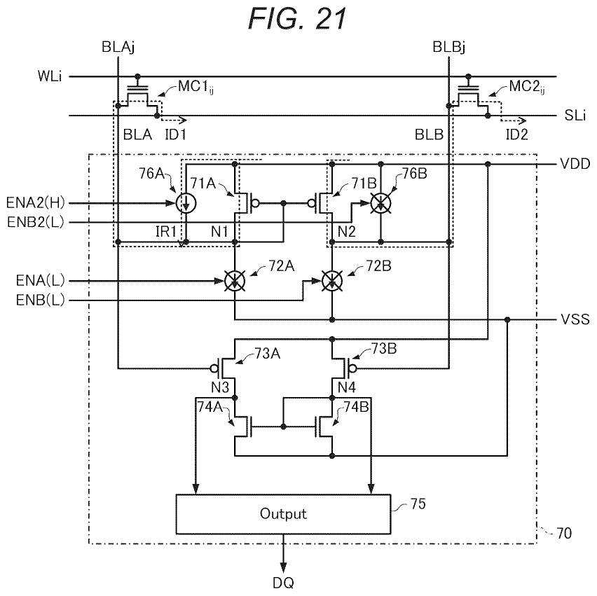

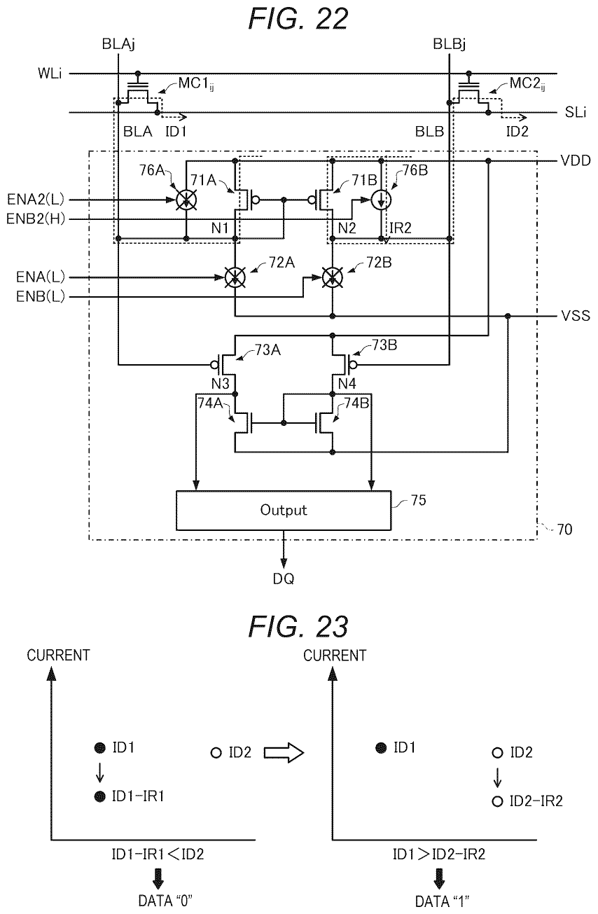

In the second mode, both of the enable signals ENA and ENB are at the low level. One of the enable signals ENA2 and ENB2 is at the low level, and the other is at the high level. FIGS. 21 and 22 show states of the readout circuit 70 when the read mode is set to the second mode. In the examples of FIGS. 21 and 22, like FIG. 20, the first detection current ID1 flows from the VDD node to the first memory cell MC1ᵢⱼ via the first node N1, and the second detection current ID2 flows from the VDD node to the second memory cell MC2ᵢⱼ via the second node N2. As shown in FIGS. 21 and 22, in the second mode, the current sources 72A and 72B stop operating, one of the current sources 76A and 76B operates, and the other stops operating.

In the example of FIG. 21, when the enable signal ENA2 is at the high level and the current source 76A operates, the first reference current IR1 flows. Accordingly, a current ID1−IR1 obtained by subtraction of the first reference current IR1 from the first detection current ID1 flows through the MOS transistor 71A. On the other hand, since the enable signal ENB2 is at the low level and the current source 76B stops operating, the second reference current IR2 does not flow, but the second detection current ID2 flows through the MOS transistor 71B. Then, the voltage V1 of the first node N1 is determined according to the current ID1−IR1 flowing through the MOS transistor 71A, and the voltage V2 of the second node N2 is determined according to the second detection current ID2 flowing through the MOS transistor 71B.

When the first memory cell MC1ᵢⱼ stores data “1” and the second memory cell MC2ᵢⱼ stores data “0”, the first detection current ID1 is larger than the second detection current ID2. Here, when the difference between the first detection current ID1 and the second detection current ID2 is larger than the first reference current IR1, the current ID1−IR1 is larger than the second detection current ID2. As a result, the voltage V1 of the first node N1 becomes lower than the voltage V2 of the second node N2, and the output circuit 75 outputs a high-level data signal DQ. When the difference between the first detection current ID1 and the second detection current ID2 is smaller than the first reference current IR1, the current ID1−IR1 is smaller than the second detection current ID2. As a result, the voltage V1 of the first node N1 becomes higher than the voltage V2 of the second node N2, and the output circuit 75 outputs a low-level data signal DQ. On the other hand, when the first memory cell MC1ᵢⱼ stores data “0” and the second memory cell MC2ᵢⱼ stores data “1”, the first detection current ID1 is smaller than the second detection current ID2. Accordingly, the current ID1 to IR1 is smaller than the second detection current ID2. As a result, the voltage V1 of the first node N1 becomes higher than the voltage V2 of the second node N2, and the output circuit 75 outputs a low-level data signal DQ.

In the example of FIG. 22, since the enable signal ENA2 is at the low level and the current source 76A stops operating, the first reference current IR1 does not flow, but the first detection current ID1 flows through the MOS transistor 71A. On the other hand, since the enable signal ENB2 is at the high level and the current source 76B operates, the second reference current IR2 flows. Accordingly, a current ID2−IR2 obtained by subtraction of the second reference current IR2 from the second detection current ID2 flows through the MOS transistor 71B. Then, the voltage V1 of the first node N1 is determined according to the first detection current ID1 flowing through the MOS transistor 71A, and the voltage V2 of the second node N2 is determined according to the current ID2−IR2 flowing through the MOS transistor 71B.

When the first memory cell MC1ᵢⱼ stores data “1” and the second memory cell MC2ᵢⱼ stores data “0”, the first detection current ID1 is larger than the second detection current ID2. Accordingly, the first detection current ID1 is larger than the current ID2−IR2. As a result, the voltage V1 of the first node N1 becomes lower than the voltage V2 of the second node N2, and the output circuit 75 outputs a high-level data signal DQ. On the other hand, when the first memory cell MC1ᵢⱼ stores data “0” and the second memory cell MC2ᵢⱼ stores data “1”, the first detection current ID1 is smaller than the second detection current ID2. Here, when the difference between the first detection current ID1 and the second detection current ID2 is larger than the second reference current IR2, the first detection current ID1 is smaller than the current ID2−IR2. As a result, the voltage V1 of the first node N1 becomes higher than the voltage V2 of the second node N2, and the output circuit 75 outputs a low-level data signal DQ. When the difference between the first detection current ID1 and the second detection current ID2 is smaller than the second reference current IR2, the first detection current ID1 is larger than the current ID2−IR2. As a result, the voltage V1 of the first node N1 becomes lower than the voltage V2 of the second node N2, and the output circuit 75 outputs a high-level data signal DQ.

As described above, in the second mode, the readout circuit 70 in the fourth embodiment reads out the complementary data stored in the first memory cell MC1ᵢⱼ and the second memory cell MC2ᵢⱼ as the data signal DQ by comparing the current ID1−IR1 obtained by subtraction of the first reference current IR1 from the first detection current ID1 flowing through the first memory cell MC1ᵢⱼ electrically coupled to the first node N1 with the second detection current ID2 flowing through the second memory cell MC2ᵢⱼ electrically coupled to the second node N2. Alternatively, in the second mode, the readout circuit 70 reads out the complementary data stored in the first memory cell MC1ᵢⱼ and the second memory cell MC2ᵢⱼ as the data signal DQ by comparing the first detection current ID1 flowing through the first memory cell MC1ᵢⱼ electrically coupled to the first node N1 with the current ID2−IR2 obtained by subtraction of the second reference current IR2 from the second detection current ID2 flowing through the second memory cell MC2ᵢⱼ electrically coupled to the second node N2.

The data reading in the second mode can be used, for example, for verification after writing of the complementary data in the first memory cell MC1ᵢⱼ and the second memory cell MC2ᵢⱼ and, when the data stored in the first memory cell MC1ᵢⱼ and the second memory cell MC2ᵢⱼ is regarded as the complementary data in the initial state, for checking whether the initial value of the complementary data is “1”, “0”, or indeterminate.

Specifically, the readout circuit 70 first subtracts the first reference current IR1 from the first detection current ID1 to read out complementary data, and then, subtracts the second reference current IR2 from the second detection current ID2 to read out complementary data. When the read two pieces of complementary data are not coincident, a margin for a determination threshold between data “1” and data “0” is insufficient. For example, as shown in FIG. 23, when the difference between the first detection current ID1 and the second detection current ID2 is smaller, the data read out with subtraction of the first reference current IR1 from the first detection current ID1 is “0”, whereas the data read out with subtraction of the second reference current IR2 from the second detection current ID2 is “1”. The two pieces of data are not coincident. For example, when the two pieces of complementary data are not coincident in the verification after writing of the complementary data, the writing is performed again. Further, in the check of the initial value of the complementary data, the data is determined as being indeterminate.

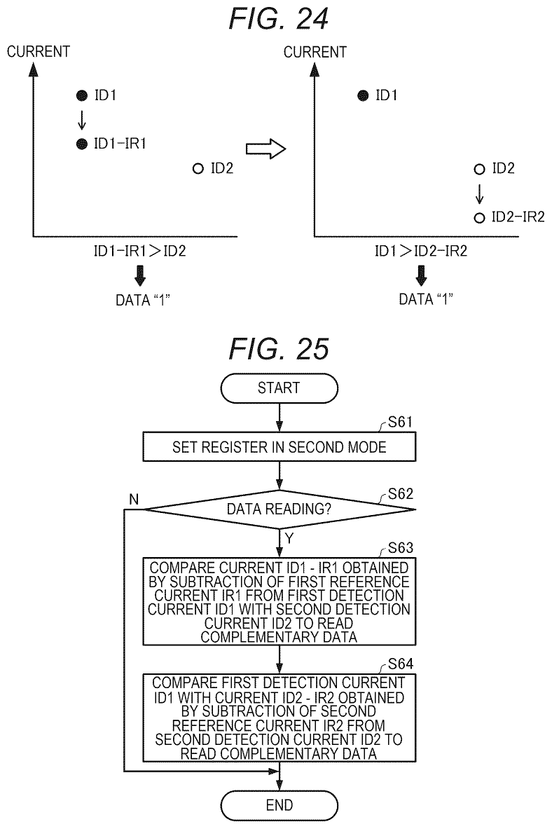

On the other hand, when the read two pieces of complementary data are coincident, the margin for the determination threshold between data “1” and data “0” is sufficient. For example, as shown in FIG. 24, when the difference between the first detection current ID1 and the second detection current ID2 is larger, data read with subtraction of the first reference current IR1 from the first detection current ID1 is “1”, and data read with subtraction of the second reference current IR2 from the second detection current ID2 is “1”. The two pieces of data are coincident. For example, when the two pieces of complementary data are coincident in verification after writing of the complementary data, re-writing is unnecessary. In the check of the initial value of the complementary data, a determination that the data is “1” or “0” is made.

Here, it is assumed that the first reference current IR1 and the second reference current IR2 are equal, and data “1” is written in one of the first memory cell MC1ᵢⱼ and the second memory cell MC2ᵢⱼ as the complementary cells, and data “0” is written in the other. In this case, when the difference between the first detection current ID1 and the second detection current ID2 is larger than the first reference current IR1 (=second reference current IR2), false reading of complementary data does not occur. Accordingly, it is not necessary to assume an excessive margin for the difference between the first detection current ID1 and the second detection current ID2, and the write time can be shortened.

FIG. 25 is a flowchart showing an example of a procedure of data reading in the second mode in the fourth embodiment. In the example of FIG. 25, first, at step S61, the second mode is set in the register 90 by an external device of the nonvolatile storage device 1. Then, at step S62, when data reading is requested from the external device, at step S63, the readout circuit 70 compares the current ID1−IR1 obtained by subtraction of the first reference current IR1 from the first detection current ID1 with the second detection current ID2 and reads out complementary data. Then, the external device acquires the read data RDT containing the complementary data output from the nonvolatile storage device 1. Further, at step S64, the readout circuit 70 compares the first detection current ID1 with the current ID2−IR2 obtained by subtraction of the second reference current IR2 from the second detection current ID2 and reads out the complementary data. Then, the external device acquires the read data RDT containing the complementary data output from the nonvolatile storage device 1. The external device can determine that the difference between the first detection current ID1 and the second detection current ID2 is sufficient when the two pieces of complementary data contained in the acquired two pieces of read data RDT are coincident, and can determine that the difference between the first detection current ID1 and the second detection current ID2 is insufficient when the two pieces of complementary data are not coincident.

Note that, like the second embodiment, the readout circuit 70 in the fourth embodiment may determine whether the first reference current IR1 is subtracted from the first detection current ID1 or the second reference current IR2 is subtracted from the second detection current ID2 based on the complementary data written in the first memory cell MC1ᵢⱼ and the second memory cell MC2ᵢⱼ, and read out the complementary data in the second mode.

Further, in the readout circuit 70 in the fourth embodiment, like the second embodiment, the readout circuit 70 may read out the complementary data stored in the first memory cell MC1ᵢⱼ and the second memory cell MC2ᵢⱼ in the first mode, determine whether to subtract the first reference current IR1 from the first detection current ID1 or subtract the second reference current IR2 from the second detection current ID2 based on the complementary data read out in the first mode, and read out the complementary data in the second mode.

Like the third embodiment, the readout circuit 70 in the fourth embodiment may read single data from the first memory cell MC1ᵢⱼ or the second memory cell MC2ᵢⱼ in the third mode. In the third mode, both of the enable signals ENA2 and ENB2 are at the low level. One of the enable signals ENA and ENB is at the low level, and the other is at the high level. That is, in the third mode, both of the current sources 76A and 76B stop operating, one of the current sources 72A and 72B operates, and the other stops operating. However, the readout circuit 70 in the fourth embodiment does not necessarily have the third mode as the operation mode like the first embodiment, and in this case, the current sources 72A and 72B may be omitted.

Other configurations and functions of the nonvolatile storage device 1 of the fourth embodiment are the same as those of the first embodiment, the second embodiment, or the third embodiment, and thus description thereof will be omitted.

In the above described nonvolatile storage device 1 of the fourth embodiment, the readout circuit 70 can read the complementary data stored in the first memory cell MC1ᵢⱼ and the second memory cell MC2ᵢⱼ by comparing the current ID1−IR1 obtained by subtraction of the first reference current IR1 from the first detection current ID1 with the second detection current ID2 in the second mode, and can read the complementary data by comparing the first detection current ID1 with the current ID2−IR2 obtained by subtraction of the second reference current IR2 from the second detection current ID2.

For example, in verification after complementary data is written in the first memory cell MC1ᵢⱼ and the second memory cell MC2ᵢⱼ, the external device may determine whether the two pieces of complementary data read out in the second mode are coincident, repeat writing of the complementary data until the two pieces of complementary data are coincident, and end writing when the difference between the first detection current ID1 and the second detection current ID2 is larger than the first reference current IR1 and the second reference current IR2. Therefore, according to the nonvolatile storage device 1 of the fourth embodiment, it is not necessary to increase the difference between the first detection current ID1 and the second detection current ID2 more than necessary and the write time can be shortened. Further, stress due to application of a high voltage at writing may be reduced and acceleration of deterioration of the first memory cell MC1ᵢⱼ and the second memory cell MC2ᵢⱼ may be reduced.

For example, in the initial state of the nonvolatile storage device 1, the external device can determine whether the initial value of the data stored in the first memory cell MC1ᵢⱼ and the second memory cell MC2ᵢⱼ is “0”, “1”, or indeterminate based on the two pieces of complementary data read out in the second mode.

According to the nonvolatile storage device 1 of the fourth embodiment, in addition to the above described effects, the same effects as those of the nonvolatile storage device 1 of the first embodiment, the second embodiment, or the third embodiment can be obtained.

### 1-5. Modified Examples

The present disclosure is not limited to the embodiments, and various modifications can be made within the scope of the gist of the present disclosure.

For example, in the above described embodiments, in the first mode, the readout circuit 70 outputs the high-level data signal DQ corresponding to data “1” when the first detection current ID1 is larger than the second detection current ID2, and outputs the low-level data signal DQ corresponding to data “0” when the first detection current ID1 is smaller than the second detection current ID2, however, the low-level data signal DQ corresponding to data “0” may be output in the former case, and the high-level data signal DQ corresponding to data “1” may be output in the latter case.

For example, in the above described first to third embodiments, the readout circuit 70 can add the reference current to either the first detection current ID1 or the second detection current ID2 in the second mode and, in the above described fourth embodiment, the readout circuit 70 can subtract the reference current from either the first detection current ID1 or the second detection current ID2 in the second mode, however, the reference current can be added and subtracted to and from only one of the first detection current ID1 and the second detection current ID2. For example, in the second mode, the readout circuit 70 may compare the current ID1+IR1 obtained by addition of the first reference current IR1 to the first detection current ID1 with the second detection current ID2 to read out complementary data, and may compare the current ID1−IR1 obtained by subtraction of the first reference current IR1 from the first detection current ID1 with the second detection current ID2 to read out complementary data. Alternatively, in the second mode, the readout circuit 70 may compare the first detection current ID1 with the current ID2+IR2 obtained by addition of the second reference current IR2 to the second detection current ID2 to read out complementary data, and may compare the first detection current ID1 with the current ID2−IR2 obtained by subtraction of the second reference current IR2 from the second detection current ID2 to read complementary data.

### 2. Integrated Circuit Device and Electronic Apparatus

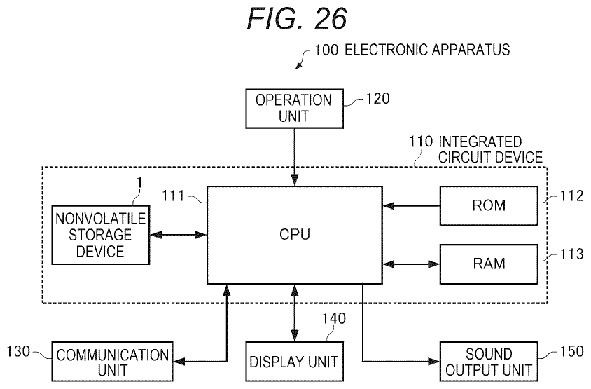

FIG. 26 is a functional block diagram showing a configuration example of an electronic apparatus using an integrated circuit device having the nonvolatile storage device 1 of any one of the above described embodiments.

An electronic apparatus 100 shown in FIG. 26 includes an integrated circuit device 110, an operation unit 120, a communication unit 130, a display unit 140, and a sound output unit 150.

The integrated circuit device 110 includes the nonvolatile storage device 1, a CPU 111 as a processor, a ROM 112, and a RAM 113. The CPU is an abbreviation for Central Processing Unit. The ROM is an abbreviation for Read Only Memory, and the RAM is an abbreviation for Random Access Memory. In the integrated circuit device 110 or the electronic apparatus 100, part of the component elements shown in FIG. 26 may be omitted or changed, or another component element may be added to the component elements shown in FIG. 26.

The CPU 111 performs processing such as data reading from the nonvolatile storage device 1 and various kinds of arithmetic processing and control processing using data supplied from the nonvolatile storage device 1 or the like according to programs stored in the nonvolatile storage device 1 or the ROM 112. That is, the CPU 111 functions as the above described external device. For example, the CPU 111 performs various kinds of data processing according to operation signals supplied from the operation unit 120, controls the communication unit 130 for data communication with the outside, generates image signals for the display unit 140 to display various kinds of images, and generates sound signals for the sound output unit 150 to output various kinds of sound.

The nonvolatile storage device 1 and the ROM 112 store programs, data, and the like for the CPU 111 to perform various kinds of arithmetic processing and control processing. The RAM 113 is used as a work area of the CPU 111, and temporarily stores the programs and data read out from the nonvolatile storage device 1 or the ROM 112, data input using the operation unit 120, calculation results executed by the CPU 111 according to the programs, and the like.

The operation unit 120 is an input device including, for example, operation keys and button switches, and outputs the operation signal corresponding to the operation by the user to the CPU 111. The communication unit 130 includes, for example, an analog circuit and a digital circuit, and performs data communication between the CPU 111 and the external device. The display unit 140 includes, for example, a display driver circuit and a liquid crystal display device, and displays various types of information based on display signals supplied from the CPU 111. The sound output unit 150 includes, for example, a sound generation circuit and a speaker, and outputs voices and various kinds of sound based on the sound signals supplied from the CPU 111.

The electronic apparatus 100 includes, for example, a smart card, a calculator, an electronic dictionary, an electronic game machine, a mobile terminal such as a cell phone, a digital still camera, a digital movie, a television, a video phone, a security television monitor, a head-mounted display, a personal computer, a printer, a network device, a car navigation system, a measurement instrument, and a medical device. The medical device includes, for example, an electronic thermometer, a sphygmomanometer, a blood glucose meter, an electrocardiogram measuring device, an ultrasonic diagnostic device, and an electronic endoscope.

According to the embodiments, the integrated circuit device 110 or the electronic apparatus 100 that maintains higher reliability over a longer period of time can be provided using the nonvolatile storage device 1 that can reduce the acceleration of the deterioration of the memory cell.

The above described embodiments and modified examples are illustrative only, and the present disclosure is not limited thereto. For example, the respective embodiments and the respective modified examples may be combined as appropriate.

The present disclosure includes substantially the same configurations as the configurations described in the embodiments, for example, a configurations having the same function, method, and result or a configuration having the same purpose and effect. The present disclosure includes a configuration in which a non-essential portion of the configuration described in the embodiment is replaced. Further, the present disclosure includes a configuration that exerts the same function and effect or a configuration that can achieve the same purpose as the configurations described in the embodiments. Furthermore, the present disclosure includes a configuration with the addition of a known technique to the configuration described in the embodiments.

The following details are derived from the above described embodiments and modified examples.

A configuration of a nonvolatile storage device includes a memory cell array having a plurality of nonvolatile memory cells including a first memory cell and a second memory cell, and a readout circuit reading out data from the memory cell array via a first node and a second node, wherein, in a first mode, the readout circuit reads out complementary data stored in the first memory cell and the second memory cell by comparing a first detection current flowing through the first memory cell electrically coupled to the first node with a second detection current flowing through the second memory cell electrically coupled to the second node, and, in a second mode, the readout circuit reads out the complementary data by comparing a current obtained by addition or subtraction of a first reference current to or from the first detection current with the second detection current, or reads out the complementary data by comparing the first detection current with a current obtained by addition or subtraction of a second reference current to or from the second detection current.

In the nonvolatile storage device, in the second mode, the readout circuit can read out the complementary data stored in the first memory cell and the second memory cell by comparing the current obtained by addition or subtraction of the first reference current to or from the first detection current with the second detection current, and can read out the complementary data by comparing the first detection current with the current obtained by addition or subtraction of the second reference current to or from the second detection current.

For example, in verification after the complementary data is written in the first memory cell and the second memory cell, an external device can determine whether two pieces of complementary data read out in the second mode are coincident, repeat writing of the complementary data until the two pieces of complementary data are coincident, and end the writing when the difference between the first detection current and the second detection current becomes larger than the first reference current and the second reference current. Therefore, according to the nonvolatile storage device, it is not necessary to increase the difference between the first detection current and the second detection current more than necessary and the write time can be shortened. Further, stress due to application of a high voltage at writing may be reduced and acceleration of deterioration of the first memory cell and the second memory cell may be reduced.

Further, for example, in the initial state of the nonvolatile storage device 1, the external device can determine whether the initial value of the data stored in the first memory cell and the second memory cell is “0”, “1”, or indeterminate based on the two pieces of complementary data read out in the second mode.

The configuration of the nonvolatile storage device may include a register that allows setting as to whether the readout circuit is operated in the first mode or the second mode from outside.

According to the nonvolatile storage device, the external device can optionally select whether to read out data in the first mode or the second mode, and thereby, versatility can be enhanced.

In the configuration of the nonvolatile storage device, in a third mode, the readout circuit may read out data stored in the first memory cell by comparing the first detection current with the second reference current, or reads out data stored in the second memory cell by comparing the second detection current with the first reference current.

According to the nonvolatile storage device, the external device can write, not complementary data, but independent single data in the first memory cell and the second memory cell, and respectively read out the two pieces of single data in the third mode. That is, according to the nonvolatile storage device, whether the complementary data or the single data is stored in each memory cell can be selected, and the external device can versatility use the memory cell array for many purposes. For example, when a plurality of different types of data are stored in the memory cell array, whether to store complementary data or single data is appropriately selected according to the characteristics of each data, and thereby, the use efficiency of the memory cell array can be increased.

The configuration of the nonvolatile storage device may include a register that allows setting as to whether the readout circuit is operated in the first mode, the second mode, or the third mode from outside.

According to the nonvolatile storage device, the external device can optionally select whether to read out data in the first mode, the second mode, and the third mode, and thereby, versatility can be enhanced.

In the configuration of the nonvolatile storage device, the readout circuit may read out the complementary data in the first mode, determine whether the first reference current is added to or subtracted from the first detection current or the second reference current is added to or subtracted from the second detection current based on the complementary data read out in the first mode, and read out the complementary data in the second mode.

According to the nonvolatile storage device, the readout circuit continuously performs reading of the complementary data in the first mode and reading of the complementary data in the second mode in response to a command from the external device, and thereby, the processing load of the external device may be reduced compared to a case where the external device commands reading of the complementary data in the first mode and further commands reading of the complementary data in the second mode.

In the configuration of the nonvolatile storage device, the readout circuit may determine whether the first reference current is added to or subtracted from the first detection current or the second reference current is added to or subtracted from the second detection current based on the complementary data written in the first memory cell and the second memory cell, and read out the complementary data in the second mode.

According to the nonvolatile storage device, since it is only necessary that the readout circuit performs reading in the second mode once for verification after writing of complementary data, the time required for the verification is shortened. Further, according to the nonvolatile storage device, the readout circuit performs data reading for verification after writing of the complementary data in response to a write command from the external device, and thereby, the processing load of the external device may be reduced compared to a case where the external device commands writing and further commands data reading for verification after the writing.

A configuration of an integrated circuit device includes the configuration of the nonvolatile storage device.

According to the integrated circuit device, the nonvolatile storage device that can reduce the acceleration of the deterioration of the first memory cell and the second memory cell storing the complementary data is provided, and thereby, higher reliability can be maintained over a longer period of time.

What is claimed is:

1. A nonvolatile storage device comprising:
a memory cell array having a plurality of nonvolatile memory cells including a first memory cell and a second memory cell; and
a readout circuit reading out data from the memory cell array via a first node and a second node, wherein
in a first mode, the readout circuit reads out complementary data stored in the first memory cell and the second memory cell by comparing a first detection current flowing through the first memory cell electrically coupled to the first node with a second detection current flowing through the second memory cell electrically coupled to the second node, and
in a second mode, the readout circuit reads out the complementary data by comparing a current obtained by addition or subtraction of a first reference current to or from the first detection current with the second detection current, or reads out the complementary data by comparing the first detection current with a current obtained by addition or subtraction of a second reference current to or from the second detection current.

2. The nonvolatile storage device according to claim 1, further comprising a register that allows setting as to whether the readout circuit is operated in the first mode or the second mode from outside.

3. The nonvolatile storage device according to claim 1, wherein
in a third mode, the readout circuit reads out data stored in the first memory cell by comparing the first detection current with the second reference current, or reads out data stored in the second memory cell by comparing the second detection current with the first reference current.

4. The nonvolatile storage device according to claim 3, further comprising a register that allows setting as to whether the readout circuit is operated in the first mode, the second mode, or the third mode from outside.

5. The nonvolatile storage device according to claim 1, wherein
the readout circuit reads out the complementary data in the first mode, determines whether the first reference current is added to or subtracted from the first detection current or the second reference current is added to or subtracted from the second detection current based on the complementary data read out in the first mode, and reads out the complementary data in the second mode.

6. The nonvolatile storage device according to claim 1, wherein
the readout circuit determines whether the first reference current is added to or subtracted from the first detection current or the second reference current is added to or subtracted from the second detection current based on the complementary data written in the first memory cell and the second memory cell, and reads out the complementary data in the second mode.

7. An integrated circuit device comprising the nonvolatile storage device according to claim 1.
